(19) United States
(12) Patent Application Publication
(10) Pub. No.: US 2025/0366178 A1
(43) Pub. Date: Nov. 27, 2025

(54) SEMICONDUCTOR DEVICE AND METHOD FOR FABRICATING THE SAME

(71) Applicant: United Microelectronics Corp., Hsinchu (TW)

(72) Inventors: ZhaoYao ZHAN, Singapore (SG); XianFeng Du, Singapore (SG); XiaoHong JIANG, Singapore (SG); Ching Hwa TEY, Singapore (SG)

(21) Appl. No.: 18/777,584

(22) Filed: Jul. 19, 2024

(30) Foreign Application Priority Data
May 23, 2024 (TW) 113119089

(51) Int. Cl. H01L 27/092; H01L 21/02; H01L 21/8256; H01L 29/24; H01L 29/49; H01L 29/66; H01L 29/76

(52) U.S. Cl. CPC H10D 84/85; H01L 21/02568; H10D 48/362; H10D 62/80; H10D 64/679; H10D 84/02; H10D 99/00

(57) ABSTRACT

A semiconductor device and a method for fabricating the semiconductor device are provided. The semiconductor device includes a plurality of device units. The device units includes a first device unit, and the first device unit includes a substrate including two source/drain regions and a gate region disposed between the two source/drain regions; a gate electrode layer disposed on the gate region, and a top surface of the gate electrode layer is coplanar to top surfaces of the two source/drain regions; a first channel layer disposed on the gate electrode layer, wherein the first channel layer includes a 2D semiconductor material; two air spacers disposed below the first channel layer and between the gate region and the two source/drain regions, respectively.

This application claims the benefit of Taiwan application Serial No. 113119089, filed May 23, 2024, the subject matter of which is incorporated herein by reference.

### BACKGROUND OF THE INVENTION

### Field of the Invention

The invention relates in general to a semiconductor device and a method for fabricating the semiconductor device, and more particularly to a semiconductor device including a two-dimensional (2D) semiconductor material and a method for fabricating the semiconductor device

### Description of the Related Art

Recently, demands for miniaturization of semiconductor devices have increased. Since the length of the channel layer in miniaturized semiconductor devices is greatly reduced, short channel effects may occur, such as large leakage current and low threshold voltage. In some examples, two-dimensional semiconductors (2D semiconductors) are used as channel materials for miniaturized semiconductor devices. 2D semiconductors have lower short channel effects. However, there are some problems with the semiconductor devices based on 2D semiconductors, such as high parasitic capacitance. Therefore, there is still an urgent need to develop an improved semiconductor device based on 2D semiconductors.

### SUMMARY OF THE INVENTION

The invention is directed to a semiconductor device having a two-dimensional (2D) semiconductor and air spacers, which can improve the problem of high parasitic capacitance of a semiconductor device based on a 2D semiconductor in general.

According to an embodiment of the present invention, a semiconductor device is provided. The semiconductor device includes a plurality of device units. The device units includes a first device unit, and the first device unit includes a substrate including two source/drain regions and a gate region disposed between the two source/drain regions; a gate electrode layer disposed on the gate region, and a top surface of the gate electrode layer is coplanar to top surfaces of the two source/drain regions; a first channel layer disposed on the gate electrode layer, wherein the first channel layer includes a 2D semiconductor material; two air spacers disposed below the first channel layer and disposed between the gate region and the two source/drain regions, respectively.

According to another embodiment of the present invention, a method for fabricating a semiconductor device is provided. The method includes the following steps: providing a substrate, wherein the substrate corresponds to a plurality of device units; forming a plurality of openings in the substrate, wherein the openings are used to define two source/drain regions and a gate region in each of the device units, and the gate region is disposed between the two source/drain regions; forming a plurality of recesses on the gate regions; forming a plurality of gate electrode layers corresponding to the recesses, wherein a top surface of the gate electrode layer is coplanar to top surfaces of the two source/drain regions; forming a first channel layer disposed on one gate electrode layer of the gate electrode layers, wherein the first channel layer comprises a two-dimensional semiconductor material; and forming two air spacers disposed below the first channel layer and disposed between the gate region and the two source/drain regions, respectively.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1 to 11B illustrate a method for fabricating a semiconductor device according to an embodiment of the present invention.

FIGS. 12A to 17B illustrate a method for fabricating a channel layer according to an embodiment of the present invention.

FIG. 18A illustrates a partial top view of a semiconductor device according to an embodiment of the present invention.

FIG. 18B illustrates a partial top view of a semiconductor device according to another embodiment of the present invention.

### DETAILED DESCRIPTION OF THE INVENTION

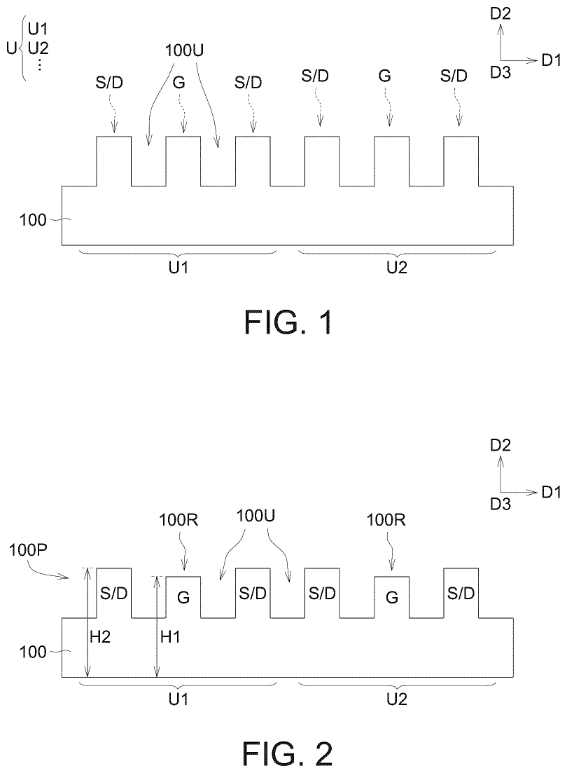

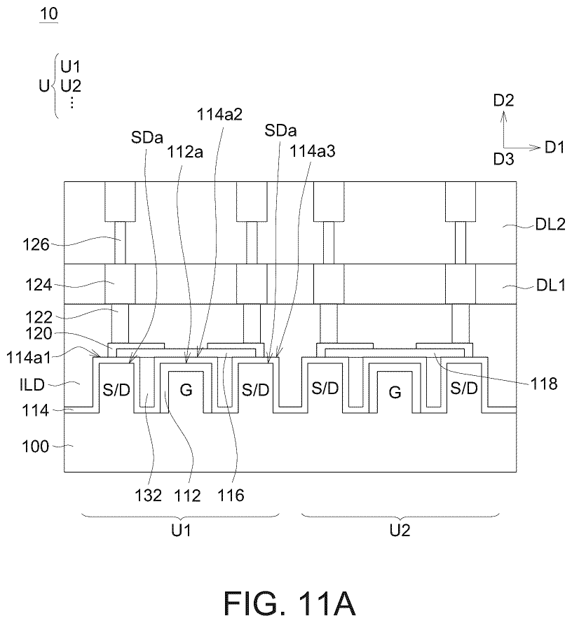

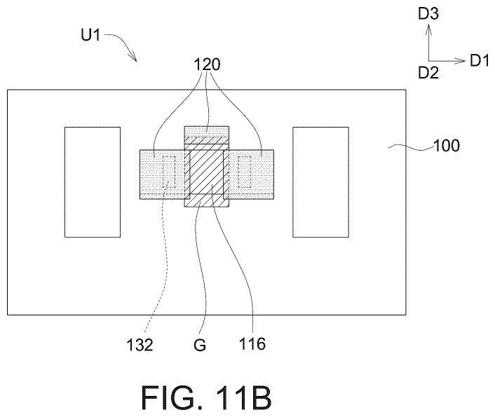

FIGS. 1 to 11B illustrate a method for fabricating a semiconductor device 10 according to an embodiment of the present invention. That is, the method for fabricating the semiconductor device 10 may include the steps shown in FIGS. 1 to 11B in sequence. FIGS. 1 to 11A illustrate cross-sectional views of the method for fabricating the semiconductor device 10. FIG. 11B illustrates a partial top view of the semiconductor device 10 as shown in FIG. 11A, for example, a simplified partial top view of a first device unit U1.

Referring to FIG. 1, a substrate 100 is provided, and then the substrate 100 is patterned, that is, a plurality of openings 100U are formed in the substrate 100, and the protruding portions of the substrate 100 between the openings 100U correspond to predetermined positions of gate regions G and the source/drain regions S/D. The substrate 100 corresponds to a plurality of device units U. The device units U are, for example, arranged along the first direction D1. The device units U include, for example, a first device unit U1, a second device unit U2, and other device units (not shown). The openings 100U are formed, for example, by an etching method, and extend along a second direction D2 and a third direction D3, for example. The first direction D1, the second direction D2 and the third direction D3 may be perpendicular to each other, but the invention is not limited thereto. The openings 100U can be used to define different device units U, and to define two source/drain regions S/D and a gate region G in each device unit U. The gate region G is disposed between the two source/drain regions S/D. In other words, the first device unit U1 and the second device unit U2 include two source/drain regions S/D and a gate region G, respectively. In some embodiments, the substrate 100 may include a shallow trench isolation (STI).

Referring to FIG. 2, a plurality of recesses 100R are formed on the gate regions G to form a preliminary structure 100P of the substrate 100, so that a height H1 of an upper surface of the substrate 100 corresponding to the gate region G in the second direction D2 is smaller than a height H2 of an upper surface of the substrate 100 corresponding to the source/drain regions S/D in the second direction D2 (i.e., H1<H2). The recesses 100R are formed by an etching method, for example.

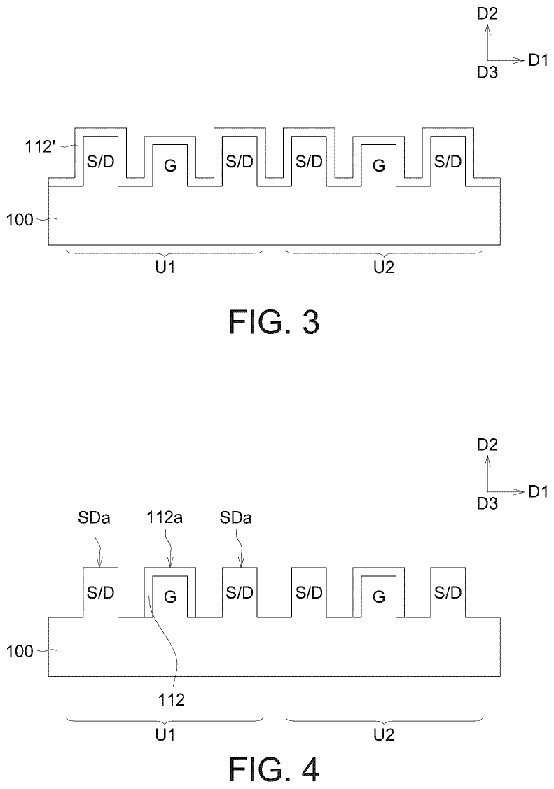

Referring to FIG. 3, a gate electrode material 112′ is formed on the preliminary structure 100P of the substrate 100. The gate electrode material 112′ is formed, for example, by a deposition method. The gate electrode material 112′ may include a conductive material, such as aluminum, gold, platinum, nickel, titanium and other metals or their alloys, or may be a commonly used compound conductor, such as titanium nitride (TiN), nitride Tantalum (TaN) or other suitable conductive material.

Referring to FIG. 4, the gate electrode material 112′ is patterned. That is, portions of the gate electrode material 112′ are removed (for example, in by an etching method) to form a plurality of gate electrode layers 112 corresponding to the recesses 100R. An upper surface 112a of the gate electrode layer 112 is coplanar to upper surfaces SDa of the two source/drain regions S/D. That is, a height of the upper surface 112a of the gate electrode layer 112 in the second direction D2 is equal to a height of the upper surfaces SDa of the two source/drain regions S/D in the second direction D2. A thickness of the gate electrode layer 112 in the second direction D2 may be equal to a depth of the recess 100R in the second direction D2, so the gate electrode layer 112 can fill a height difference between the upper surface of the gate region G and upper surfaces SDa of the source/drain region S/D.

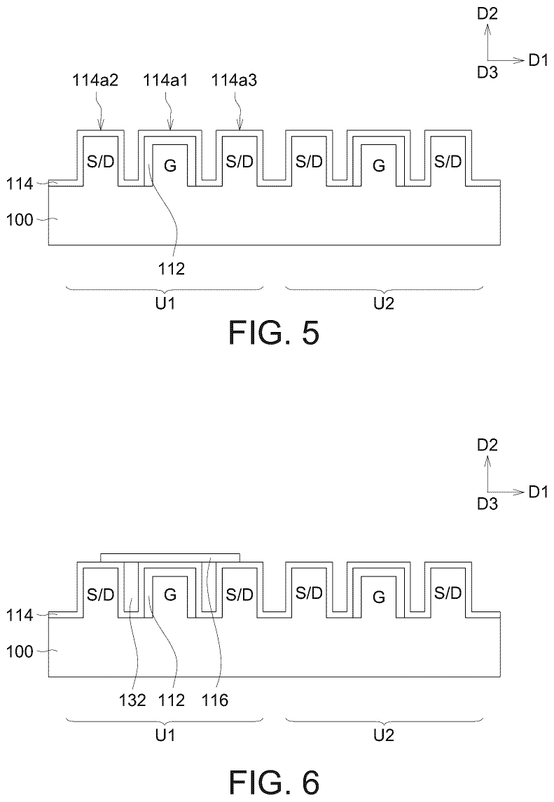

Referring to FIG. 5, a dielectric layer 114 is formed on the preliminary structure 100P and the gate electrode layer 112 (i.e., on the source/drain regions S/D and the gate electrode layer 112). In some embodiments, the dielectric layer 114 may have a uniform thickness, and an upper surface 114a1 of the dielectric layer 114 disposed on the gate electrode layer 112 and upper surfaces 114a1 and 114a2 of the dielectric layer 114 disposed on the two source/drain regions S/D may be coplanar. That is, heights of the upper surface 114a1 and the upper surfaces 114a1 and 114a2 in the second direction D2 may be the same. The dielectric layer 114 is formed, for example, by a deposition method. The material of the dielectric layer 114 may include a high-k material.

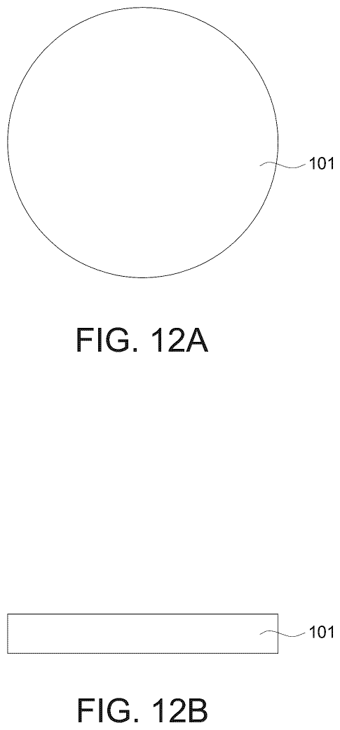

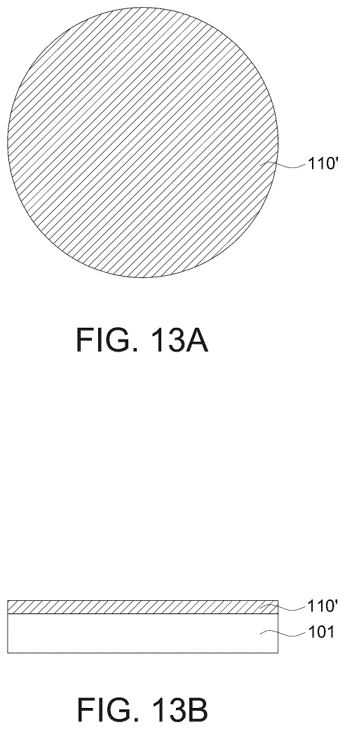

Referring to FIG. 6, a first channel layer 116 is formed on a gate electrode layer 112 corresponding to the first device unit U1 in the plurality of gate electrode layers 112, wherein the first channel layer 116 includes a two-dimensional (2D) semiconductor material. The first channel layer 116 is formed on the dielectric layer 114 on the corresponding gate region G and the source/drain regions S/D. After the first channel layer 116 is formed, two air spacers 132 are formed under the first channel layer 116 and are respectively disposed between the gate region G and the two source/drain regions S/D. In the present embodiment, the first channel layer 116 overlaps the gate region G, the gate electrode layer 112, the two source/drain regions S/D and the dielectric layer 114 in the first device unit U1 in the second direction D2. In some embodiments, the steps of forming the first channel layer 116 may include first forming a first channel material film, then transferring the first channel material film to the dielectric layer 114, and then patterning the first channel material film. That is, an excess portion of the first channel material film is removed, and a remaining portion of the first channel material film forms the first channel layer 116. The steps for forming the first channel material film are described in detail below (as shown in FIGS. 12A to 17B).

Referring to FIG. 7, a second channel layer 118 is formed on a gate electrode layer 112 corresponding to the second device unit U2 in the plurality of gate electrode layers 112, wherein the second channel layer 118 includes a 2D semiconductor material. The second channel layer 118 is formed on the dielectric layer 114 on the corresponding gate region G and source/drain regions S/D. After the second channel layer 118 is formed, two air spacers 132 are formed under the second channel layer 118 and respectively disposed between the gate region G and the two source/drain regions S/D. In the present embodiment, the second channel layer 118 overlaps the gate region G, the gate electrode layer 112, the two source/drain regions S/D and the dielectric layer 114 in the second device unit U2 in the second direction D2. In some embodiments, the steps of forming the second channel layer 118 may include first forming a second channel material film, then transferring the second channel material film to the dielectric layer 114, and then patterning the second channel material film. That is, an excess portion of the second channel material film is removed, and a remaining portion of the second channel material film forms the second channel layer 118. The steps for forming the second channel material film are described in detail below (as shown in FIGS. 12A to 17B).

According to an embodiment, the first channel layer 116 includes an N-type channel material, and the second channel layer 118 includes a P-type channel material. According to another embodiment, the first channel layer 116 includes a P-type channel material and the second channel layer 118 includes an N-type channel material.

In some embodiments, the N-type channel material and the P-type channel material include different two-dimensional semiconductor materials. The N-type channel material may include an N-type channel 2D semiconductor material. The N-type channel 2D semiconductor material may be molybdenum disulfide (MoS₂), rhenium disulfide (ReS₂), tungsten disulfide (WS₂) or other suitable 2D semiconductor material. The P-type channel material may include a P-type channel 2D semiconductor material. The P-type channel 2D semiconductor material may be black phosphorus (BP), molybdenum ditelluride (MoTe₂), molybdenum diselenide (MoSe₂), Tungsten selenide (WSe₂) or other suitable 2D semiconductor material. The carrier type of 2D semiconductor materials can be adjusted through an alternative doping during the growth process. For example, molybdenum disulfide can be converted into a P-type channel material through niobium (Nb) doping during the growth process of molybdenum disulfide.

In some embodiments, the N-type channel material or P-type channel material can be derived from the same 2D semiconductor material, but converted to another conductivity type through surface charge transfer doping. For example, before growing the oxide hafnium dioxide (HfO2), the original P-type channel material tungsten diselenide (WSe2) can be well converted to N-type channel material by evaporating a thin seed layer of aluminum (AI). This technology simplifies the manufacturing of 2D complementary metal oxide semiconductors (2D CMOS) by eliminating the need to grow and process two separate materials, P-type metal oxide semiconductor (PMOS) and N-type metal oxide semiconductor (NMOS).

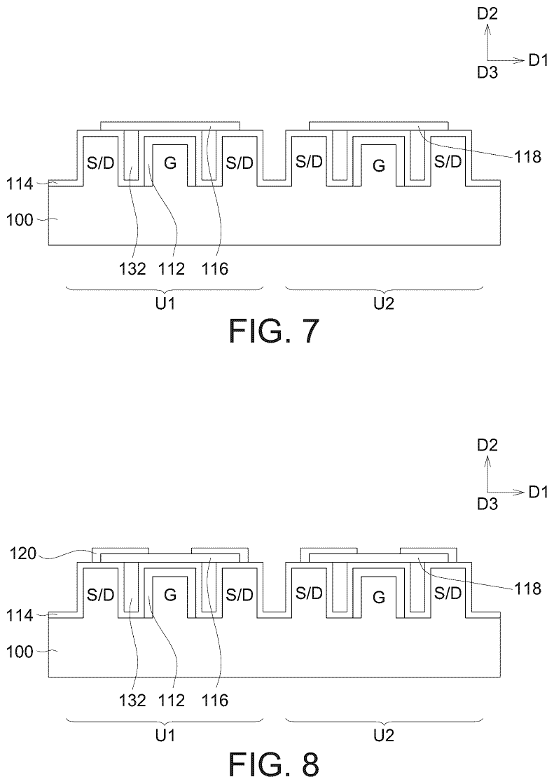

Referring to FIG. 8, three source/drain/gate electrodes 120 are respectively formed in the first device unit U1 and the second device unit U2, and the source/drain/gate electrodes 120 are disposed on the source/drain regions S/D and the gate region G (as shown in FIG. 11B). In some embodiments, the source/drain/gate electrodes 120 in the first device unit U1 and the second device unit U2 may be different conductive metals or compounds.

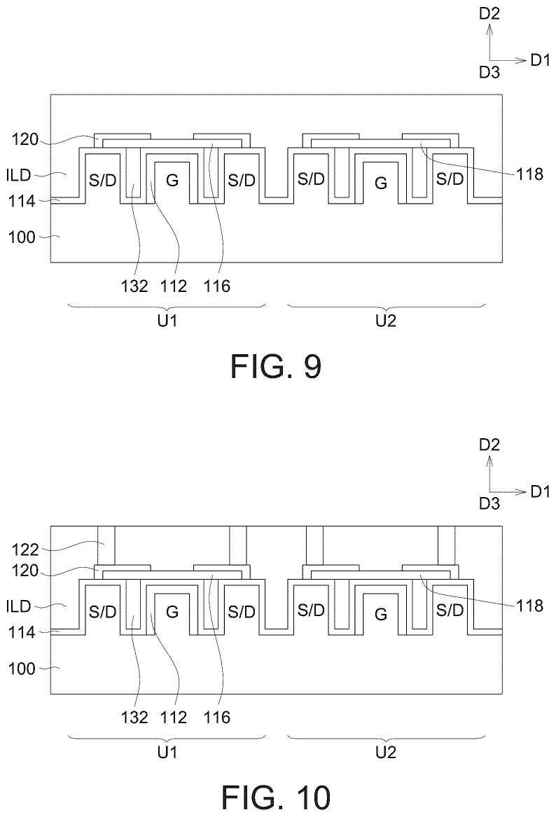

Referring to FIG. 9, an interlayer dielectric ILD is formed on the source/drain/gate electrodes 120. That is, the interlayer dielectric ILD is disposed on the entire structure as shown in FIG. 8 above and covers the entire area of the substrate 100. The interlayer dielectric ILD is formed by a deposition method, for example. The steps for forming the interlayer dielectric ILD may include a planarization process, such as chemical-mechanical polishing.

Referring to FIG. 10, source/drain/gate contacts 122 are formed on the source/drain/gate electrodes 120. This step is similar to the middle-of-line process (MOL process) in a general semiconductor process, and the detailed steps will not be described.

Referring to FIG. 11A, through holes 124 and the upper contacts 126 are formed on the source/drain/gate contacts 122. For example, an intermediate dielectric layer DL1 is formed first, and then the source/drain/gate contacts 122 penetrating through the intermediate dielectric layer DL1 is formed. Thereafter, a top dielectric layer DL2 is formed, and then upper contacts 126 penetrating through the top dielectric layer DL2 are formed. This step is similar to the back-end-of-line process (BEOL process) in a general semiconductor process, and the detailed steps will not be described.

In this way, the semiconductor device 10 shown in FIGS. 11A to 11B is formed. The semiconductor device 10 includes a plurality of device units U. The device unit U includes a first device unit U1 and a second device unit U2 (it may further include other device units). In some embodiments, the device unit U includes a plurality of first device units U1 and a plurality of second device units U2. The first device unit U1 includes a substrate 100, a gate electrode layer 112, a dielectric layer 114, a first channel layer 116, three source/drain/gate electrodes 120 and two air spacers 132. The substrate 100 includes two source/drain regions S/D and a gate region G. The gate region G is disposed between the two source/drain regions S/D. One of the two source/drain regions S/D is the source region and the other is the drain region. The gate electrode layer 112 is disposed on the gate region G, and the upper surface 112a of the gate electrode layer 112 is coplanar to the upper surfaces SDa of the two source/drain regions S/D. The first channel layer 116 is disposed on the gate electrode layer 112, wherein the first channel layer 116 includes a 2D semiconductor material. The air spacers 132 are disposed under the first channel layer 116 and respectively disposed between the gate region G and the two source/drain regions S/D. The second device unit U2 is similar to the first device unit U1. The difference between the second device unit U2 and the first device unit U1 is that the second device unit U2 includes a second channel layer 118 instead of the first channel layer 116. For example, the air spacers 132 are disposed below the second channel layer 118. Other identical parts will not be described in detail.

As shown in FIG. 11A, the dielectric layer 114 is disposed on the source/drain regions S/D and the gate electrode layer 112. That is, the dielectric layer 114 continuously extends on the source/drain regions S/D and the gate electrode layers 112 of the first device unit U1 and the second device unit U2. The first channel layer 116 and the second channel layer 118 extend on the dielectric layer 114. The source/drain/gate electrodes 120 are disposed on the source/drain/gate regions S/D/G, and are in electrical contact with the first channel layer 116 and the second channel layer 118. In the second direction D2, the source/drain/gate electrodes 120 may overlap the dielectric layer 114, the first channel layer 116 (or the second channel layer 118), and the air spacers 132. The air spacers 132 in the first device unit U1 are provided between the dielectric layer 114 and the first channel layer 116. The air spacers 132 in the second device unit U2 are disposed between the dielectric layer 114 and the second channel layer 118. According to some embodiments, the semiconductor device 10 further includes an interlayer dielectric ILD. The interlayer dielectric ILD is disposed on the source/drain/gate electrodes 120. That is, the interlayer dielectric ILD covers the dielectric layer 114, the first channel layer 116, the second channel layer 118 and the source/drain/gate electrodes 120. Furthermore, the first channel layer 116 and the second channel layer 118 are in contact with the interlayer dielectric ILD. The source/drain/gate contacts 122 penetrate through the interlayer dielectric ILD to electrically contact the source/drain/gate electrodes 120. The middle dielectric layer DL1 and the top dielectric layer DL2 may be sequentially disposed on the interlayer dielectric ILD and the source/drain/gate contacts 122. The through holes 124 penetrate through the middle dielectric layer DL1, and the upper contact 126 penetrate through the top dielectric layer DL2, so that the through holes 124 are in electrical contact with the source/drain/gate contacts 122, and the upper contacts 126 is in electrical contact with the through holes 124.

Compared to a comparative example of a semiconductor device in which the channel layer does not include a 2D semiconductor material, since the first channel layer 116 and the second channel layer 118 according to an embodiment of the present invention include a 2D semiconductor material having an inert and smooth surface. The first channel layer 116 and the second channel layer 118 have lower short channel effect and have no problem of reduced charge mobility even in miniaturized semiconductor devices. In some embodiments, a thickness of a single layer of 2D semiconductor material may be 0.2 to 2 nanometers, while in other embodiments, few layers of 2D semiconductor material may also be used.

In the present embodiment, the upper surface 112a of the gate electrode layer 112 and the upper surfaces SDa of the two source/drain regions S/D are coplanar (as shown in FIG. 11), and the corresponding upper surfaces 1141a1 to 1141a3 of the dielectric layer 114 formed on the gate electrode layer 112 and the source/drain regions S/D can also be co-planar accordingly, thus providing a flat surface for the first channel layer 116 and the second channel layer 118. Compared with the comparative example of a semiconductor device having a channel layer with a sharp structure below, since the structures below the first channel layer 116 and the second channel layer 118 of the present embodiment are flat and have no sharp structures, the first channel layer 116 and the second channel layer 118 will not be punctured by sharp structures, and will not be affected by the stress of sharp structures (less likely to be stretched or deformed). Therefore, the first channel layer 116 and the second channel layer 118 can have good charge mobility, so the semiconductor device 10 can have excellent performance.

Compared with a comparative example of a semiconductor device without an air spacer, since the semiconductor device 10 according to an embodiment of the present application includes the air spacers 132, the parasitic capacitance can be reduced and the response speed of the semiconductor device can be improved.

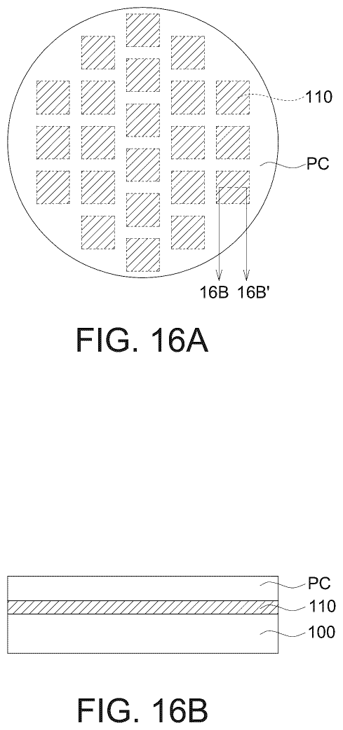

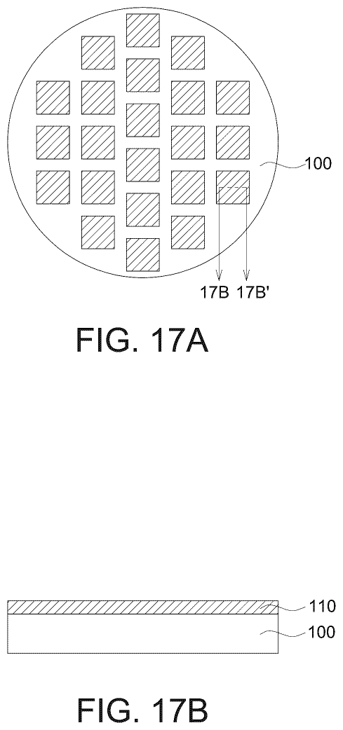

FIGS. 12A to 17B illustrate a method for fabricating the channel layer 110 according to an embodiment of the present invention. That is, the method for fabricating the channel layer 110 includes the steps shown in FIGS. 12A to 17B in sequence. The channel layer 110 may be the aforementioned first channel layer 116, second channel layer 118 or other channel layers. FIGS. 12A to 17A are top views, and FIGS. 12B to 17B are cross-sectional views of FIGS. 12A to 17A respectively. FIG. 16B shows a cross-sectional view taken along line 16B-16B′ in FIG. 16A. FIG. 17B shows a cross-sectional view taken along line 17B-17B′ in FIG. 17A. FIGS. 12B-15B can correspond to cross-sectional positions as shown in FIGS. 16B-17B, and can also be the other cross-sectional positions in FIGS. 12A-15A.

Referring to FIGS. 12A and 12B at the same time, a growth matrix 101 is provided.

Referring to FIGS. 13A and 13B at the same time, a channel material film 110′ is formed on the growth matrix 101.

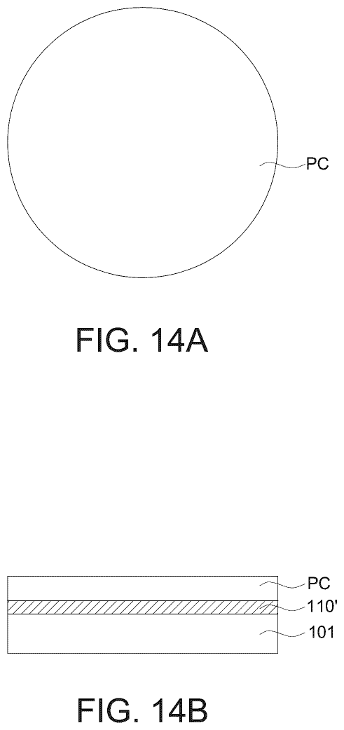

Referring to FIGS. 14A and 14B at the same time, a polymer coating PC is formed on the channel material film 110′.

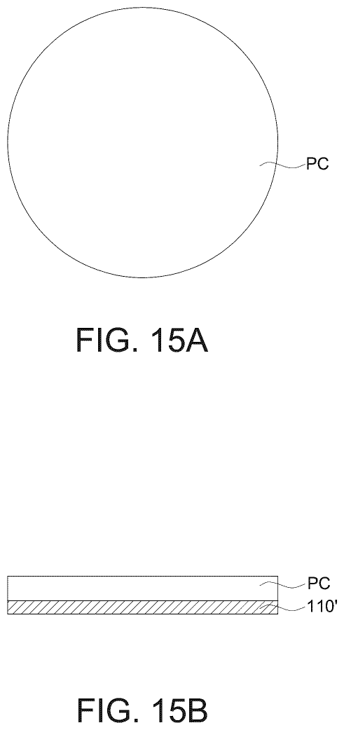

Referring to FIGS. 15A and 15B at the same time, a stacked structure formed by the growth matrix 101, the channel material film 110′ and the polymer coating PC are separated.

Referring to FIGS. 16A and 16B at the same time, the stacked structure formed by the channel material film 110′ and the polymer coating PC is transferred to a patterned substrate 100 (for example, the substrate 100 as shown in FIG. 5), and the channel material film 110′ is patterned to form the channel layer 110. For example, an excess portion of the first channel material film is removed, and a remaining portion of the first channel material film forms the first channel layer 116. Alternatively, an excess portion of the second channel material film is removed, and a remaining portion of the second channel material film forms the second channel layer 118.

Referring to FIGS. 17A and 17B at the same time, the polymer coating PC is removed and the channel layer 110 is exposed for subsequent processes (such as the subsequent process for forming another channel layer, the subsequent process for forming source/drain/gate electrodes 120 or other processes).

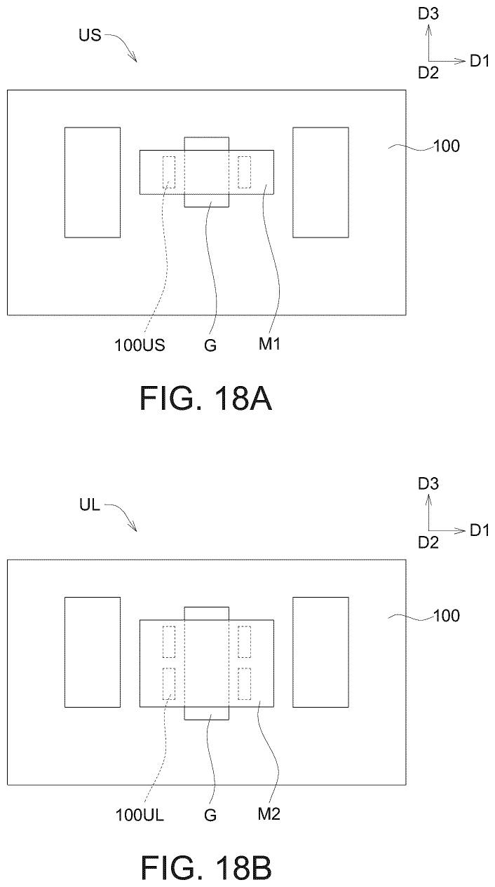

FIG. 18A illustrates a partial top view of a semiconductor device 10 according to an embodiment of the present invention.

As shown in FIG. 18A, the device unit U may include a small device unit US. In the small device unit US, openings 100US extend continuously along the third direction D3. The openings 100US may correspond to the aforementioned openings 100U. The channel layer M1 extends on the openings 100US and the gate region G. The channel layer M1 may correspond to the aforementioned first channel layer 116, second channel layer 118 or other channel layers.

FIG. 18B illustrates a partial top view of a semiconductor device 10 according to another embodiment of the present invention.

As shown in FIG. 18B, the device unit U may include a large device unit UL. In the large device unit UL, openings 100UL may be a plurality of openings spaced apart in the third direction D3. That is, the openings 100UL may extend discontinuously in the third direction D3, for example. In the present embodiment, one opening 100UL includes two openings spaced apart in the third direction D3. However, the invention is not limited thereto. In other embodiments, the opening 100UL includes a plurality of air spacers spaced apart in the third direction D3. The openings 100UL may correspond to the aforementioned openings 100U. The channel layer M2 extends on the openings 100UL and the gate region G. The channel layer M2 may correspond to the aforementioned first channel layer 116, the second channel layer 118, or other channel layers. According to some embodiments, the size of the large device unit UL is larger than the size of the small device unit US.

According to the above content, a semiconductor device according to an embodiment of the present invention includes a plurality of device units, wherein the device unit includes a first device unit. The first device unit includes a substrate, a gate electrode layer, a first channel layer and two air spacers. The substrate includes two source/drain regions and a gate region. The gate region is disposed between the two source/drain regions. The gate electrode layer is disposed on the gate region, and an upper surface of the gate electrode layer is coplanar to upper surfaces of the two source/drain regions. The first channel layer is disposed on the gate electrode layer, wherein the first channel layer includes 2D semiconductor material. The two air spacers disposed below the first channel layer and between the gate region and the two source/drain regions, respectively. Compared to a comparative example of a semiconductor device in which the channel layer does not include a 2D semiconductor material, since the first channel layer according to an embodiment of the present invention includes a 2D semiconductor material having an inert and smooth surface, which can have a lower short channel effect and have no problem of reduced charge mobility even in miniaturized semiconductor devices. Compared with the comparative example of a semiconductor device having a channel layer with a sharp structure below, since the upper surface of the gate electrode layer is coplanar to upper surfaces of the two source/drain regions in the present invention, and the structures below the first channel layer of the present invention are flat and have no sharp structures, the first channel layer will not be punctured by sharp structures, and will not be affected by the stress of sharp structures (less likely to be stretched or deformed). Therefore, the first channel layer can have good charge mobility, so the semiconductor device can have excellent performance. Compared with a comparative example of a semiconductor device without an air spacer, since the semiconductor device according to an embodiment of the present application includes the air spacers, the parasitic capacitance can be reduced and the response speed of the semiconductor device can be improved.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a plurality of device units, wherein the device units comprises a first device unit, and the first device unit comprises:
a substrate comprising two source/drain regions and a gate region disposed between the two source/drain regions;
a gate electrode layer disposed on the gate region, wherein a top surface of the gate electrode layer is coplanar to top surfaces of the two source/drain regions;
a first channel layer disposed on the gate electrode layer, wherein the first channel layer includes a two-dimensional semiconductor material; and
two air spacers disposed below the first channel layer and disposed between the gate region and the two source/drain regions, respectively.

2. The semiconductor device according to claim 1, wherein the first device unit further comprises a dielectric layer disposed on the two source/drain regions and the gate electrode layer.

3. The semiconductor device according to claim 2, wherein the first channel layer extends on the dielectric layer.

4. The semiconductor device according to claim 1, wherein the first device unit further comprises three source/drain/gate electrodes disposed on the two source/drain regions and the gate region.

5. The semiconductor device according to claim 4, further comprising an interlayer dielectric disposed on the three source/drain/gate electrodes.

6. The semiconductor device according to claim 5, wherein the first channel layer contacts the interlayer dielectric.

7. A method for fabricating a semiconductor device, comprising:
providing a substrate, wherein the substrate corresponds to a plurality of device units;
forming a plurality of openings in the substrate, wherein the openings are used to define two source/drain regions and a gate region in each of the device units, and the gate region is disposed between the two source/drain regions;
forming a plurality of recesses on the gate regions;
forming a plurality of gate electrode layers corresponding to the recesses, wherein a top surface of the gate electrode layer is coplanar to top surfaces of the two source/drain regions;
forming a first channel layer disposed on one gate electrode layer of the gate electrode layers, wherein the first channel layer comprises a two-dimensional semiconductor material; and
forming two air spacers disposed below the first channel layer and disposed between the gate region and the two source/drain regions, respectively.

8. The method according to claim 7, further comprising forming a dielectric layer disposed on the two source/drain regions and the gate electrode layer.

9. The method according to claim 8, wherein the first channel layer extends on the dielectric layer.

10. The method according to claim 7, further comprising forming three source/drain/gate electrodes disposed on the two source/drain regions and the gate region.

11. The method according to claim 10, further comprising forming an interlayer dielectric disposed on the three source/drain/gate electrodes.

12. The method according to claim 11, wherein the first channel layer contacts the interlayer dielectric.
